(19) United States
(12) Patent Application Publication
(10) Pub. No.: US 2020/0124900 A1
(43) Pub. Date: Apr. 23, 2020

(54) FLEXIBLE LIQUID CRYSTAL OPTICAL SHUTTER AND MANUFACTURING METHOD THEREOF

(71) Applicants: South China Normal University, Guangzhou (CN); Shenzhen Guohua Optoelectronics Co., Ltd,, Shenzhen (CN); Academy of Shenzhen Guohua Optoelectronics, Shenzhen (CN)

(72) Inventors: Guofu ZHOU, Guangzhou (CN); Dong YUAN, Guangzhou (CN); Xiaowen HU, Guanghou (CN); Xudong YAN, Guangzhou (CN); Wei ZHAO, Guangzhou (CN); Mingliang JIN, Guangzhou (CN)

(21) Appl. No.: 16/605,531

(22) PCT Filed: Oct. 10, 2018
(86) PCT No.: PCT/CN2018/109639

§ 371 Date: Oct. 16, 2019

(30) Foreign Application Priority Data
Apr. 11, 2018 (CN) 201810321885.3

(51) Int. Cl. G02F 1/1333; G03B 9/08; G02F 1/1337; G02F 1/1341; G02F 1/1343; G03F 7/00; G03F 7/20; G03F 7/031; C09K 19/38

(52) U.S. Cl. CPC G02F 1/133305; G03B 9/08; G02F 1/1337; G02F 1/1341; G02F 1/13439; C09K 2219/03; G03F 7/2004; G03F 7/031; C09K 19/3852; G02F 2001/133742; G02F 2202/043; G03F 7/0007

(57) ABSTRACT

A flexible liquid crystal optical shutter and a manufacturing method thereof are disclosed. A box body filled with a liquid crystal mixture is irradiated with ultraviolet light to form supporting column structures, which increases the bending resistance of the flexible liquid crystal optical shutter, and may improve the mechanical stability of the liquid crystal optical shutter while maintaining the haze of the flexible liquid crystal optical shutter. The manufacturing method is simple. After the manufactured flexible liquid crystal optical shutter is connected to a power supply, the brightness of the liquid crystal optical shutter may be adjusted by changing the magnitude of voltage applied, so that the liquid crystal optical shutter may replace curtains to some extent, solves some limitations of coated glass, and has a good application prospect in vehicle-mounted household glass windows and the like.

### TECHNICAL FIELD

The present invention relates to the field of displays, and more particularly to a flexible liquid crystal optical shutter and a manufacturing method thereof.

### BACKGROUND

Previous intelligent optical switches are used glass as the substrate. The glass is easy to be broken and high in cost. In addition, previous glass intelligent windows are difficult to store during the using process. Based on the above reasons, coated glass at home and abroad is difficult to apply broadly in a large number of home buildings and the use in lives.

In recent years, flexible perspective displays have been considered as one of the next-generation displays. Particularly, flexible perspective displays using organic light-emitting diodes (OLEDs) have been extensively studied. The OLEDs have great potential of application in the display field due to the advantages of fast response, wide viewing angle, high brightness and applicable to flexible displays, etc. In order to apply optical shutters to flexible straight-through displays, it is very important to manufacture the optical shutters by flexible conductive substrates, and the flexible displays which can be folded or rolled up without damage are predicted to be the mainstream of displays at the same time. The present flexible display mainly apply a flexible substrate and a bending stress resistant transparent electrode. However, due to repeated mechanical stimulation such as bending, cracks may be produced in an electrode layer such as an ITO electrode, and cause a sharp increase in resistance, thereby reducing the performance of the flexible display. Therefore, it is necessary to find an optical shutter device with relatively high bending-resistant mechanical property, which may replace curtains to some extent and solve some limitations of coated glass, and be widely applied in vehicle-mounted home glass windows and the like.

### SUMMARY

In view of the deficiencies of the prior art, the technical problem to be solved by the present invention is to provide a flexible liquid crystal optical shutter and a manufacturing method thereof.

The technical solution adopted by the present invention is:

The present invention provides a method for manufacturing a flexible liquid crystal optical shutter, comprising the following steps:

S1, taking or manufacturing a box body, comprising an upper substrate and a lower substrate, which are arranged oppositely, wherein the upper substrate comprises a first transparent flexible substrate, a first conductive layer and a first vertical alignment layer, which are sequentially stacked arranged; wherein the lower substrate comprises a second transparent flexible substrate, a second conductive layer and a second vertical alignment layer, which are sequentially stacked arranged; an adjustment region is formed between the upper substrate and the lower substrate, and the first vertical alignment layer and the second vertical alignment layer faces the adjustment region;

S2, filling the adjustment region with a liquid crystal mixture, wherein the liquid crystal mixture comprises a photopolymerizable liquid crystal monomer, a photoinitiator and a negative liquid crystal;

S3, placing a mask with a transparent portion and an opaque portion above the box body, and irradiating the mask with ultraviolet light, to polymerize the liquid crystal mixture corresponding to the transparent portion polymerize to form supporting structures;

S4, removing the mask, and irradiating the box body with an intensity of the ultraviolet light is 25-35 mW/cm².

Preferably, the intensity of the ultraviolet light in step S3 is 80-100 mW/cm².

Preferably, the irradiation time of the ultraviolet light in step S3 is 4-6 min.

Preferably, the irradiation time of the ultraviolet light in step S4 is 8-12 min.

Preferably, the liquid crystal mixture comprises 8-12 parts by mass of polymerizable liquid crystal monomer, 0.5-1.5 parts by mass of photoinitiator, and 84.5-91 parts by mass of negative liquid crystal.

Preferably, the liquid crystal mixture further comprises a dichroic dye, and more preferably, the liquid crystal mixture comprises 8-12 parts by mass of polymerizable liquid crystal monomer, 0.5-1.5 parts by mass of photoinitiator, 84.5-91 parts by mass of negative liquid crystal, and 0.5-2 parts by mass of dichroic dye.

More preferably, the dichroic dye comprises a dichroic black dye. The dichroic black dye filled in the present invention may be a single dichroic black dye or a mixture of other dyes in a certain ratio. When the black dye is used, the flexible liquid optical crystal shutter is displayed as black due to the occurrence of the light absorption phenomenon of the black dye, which well solves that a flexible perspective OLED display may be affected by the poor visibility due to the inability to display as black. In addition, in the state of voltage application, there is the light absorption phenomenon occurring in the black dye molecules and making the higher haze of optical shutter and better usage effect.

Preferably, the polymerizable liquid crystal monomer is HCM009 (Jiangsu Hecheng Display Technology Co., Ltd.), the professional name is: RM82, and the chemical structural formula is:

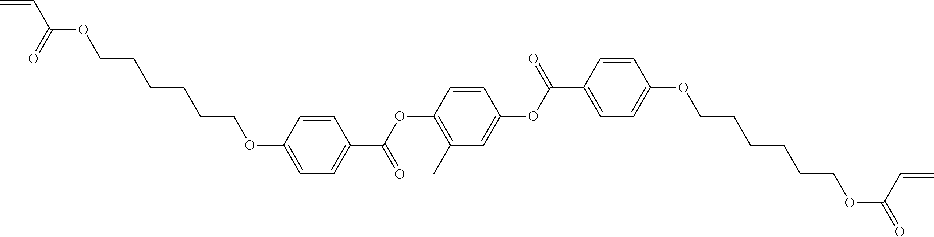 [SMILES: C=CC(=O)OCCCCCCOc1ccc(C(=O)Oc2ccc(OC(=O)c3ccc(OCCCCCCOC(=O)C=C)cc3)c(C)c2)cc1]

Preferably, the photoinitiator is IR651, and the structural formula is:

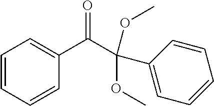 [SMILES: COC(OC)(C(=O)c1ccccc1)c1ccccc1]

Preferably, the negative liquid crystal is at least one of HNG30400-200, HNG60700-200, and HNG741200-000 (Jiangsu Hecheng Display Technology Co., Ltd.).

Preferably, photo spacers for controlling the thickness of the box body are arranged in the adjustment region.

Preferably, the first conductive layer or the second conductive layer is any one of an ITO layer or a silver nanowire transparent electrode layer.

The present invention also provides a flexible liquid crystal optical shutter which is manufactured by the above method for manufacturing a flexible liquid crystal optical shutter.

The present invention has the following advantages:

The present invention provides a method for manufacturing a flexible liquid crystal optical shutter, using the supporting structures formed by the mask to increase the bending-resistant property of the optical shutter, and may improve the mechanical stability of the liquid crystal optical shutter while on the condition of maintaining the haze of the flexible liquid crystal optical shutter. When no voltage is applied to the liquid crystal optical shutter provided by the present invention, the negative liquid crystal and the dye molecules are arranged in a single domain with the flexible transparent substrates, and the transmittance of light reaches the highest level at the moment. When a voltage is applied between the two flexible transparent substrates, the negative liquid crystal turns toward a direction parallel to the flexible transparent substrates, and drives the dye molecules to rotate. During the process of applying the voltage, the negative liquid crystal after turning and dye molecules are arranged randomly in the box body and irregularly distributed around the supporting structures, so that the liquid crystal optical shutter converts from a light transmission state to a light scattering state. The brightness of the liquid crystal optical shutter may be adjusted by adjusting the magnitude of the applied voltage, so that the liquid crystal optical shutter may replace curtains to some extent, solves some limitations of coated glass, and has a good application prospect in vehicle-mounted home glass windows and the like.

### BRIEF DESCRIPTION OF THE DRAWINGS

FIG. 1 is a cross-sectional view of a flexible liquid crystal optical shutter in the present invention;

FIG. 2 is a schematic diagram of a manufacturing process of the flexible liquid crystal optical shutter in the present invention;

FIG. 3 is a schematic diagram of structure of a mask;

FIG. 4 is a cross-sectional view of the flexible liquid crystal optical shutter when no voltage is applied;

FIG. 5 is a cross-sectional view of the flexible liquid crystal optical shutter when voltage is applied;

FIG. 6 is a haze curve diagram of the flexible liquid crystal optical shutter before bending;

FIG. 7 is a haze curve diagram of the flexible liquid crystal optical shutter bent by a cylinder of R=30 mm for 24 h;

FIG. 8 is a haze curve diagram of the flexible liquid crystal optical shutter bent by a cylinder of R=50 mm for 24 h;

FIG. 9 is a haze curve diagram of the flexible liquid crystal optical shutter bent by a cylinder of R=70 mm for 24 h;

FIG. 10 is an overlying diagram of the haze curves in FIGS. 6-9.

### DETAILED DESCRIPTION

In combination of embodiments, the concept and the technical effects of the present invention are clearly and completely described in the following detailed description of the present invention to fully understand the objects, features and effects of the present invention. It is apparent that the described embodiments are only a part of the embodiments of the present invention, instead of all the embodiment. Based on the embodiments of the present invention, other embodiments obtained by those skilled in the art without creative efforts also belong to the scope of protection of the present invention.

### Embodiment 1

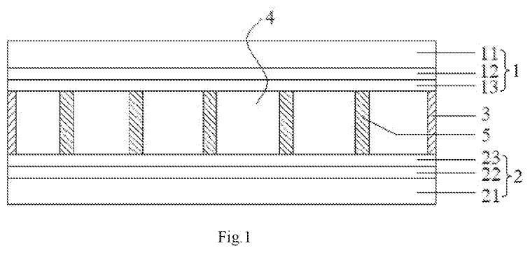

Referring to FIG. 1, this embodiment provides a flexible liquid crystal optical shutter comprising an upper substrate 1 and a lower substrate 2. The upper substrate 1 comprises a first transparent flexible substrate 11, a first transparent ITO electrode layer 12 arranged on a surface of the first transparent flexible substrate 11, and a first vertical alignment layer 13 coated on the first ITO electrode layer 12. The lower substrate 2 comprises a second transparent flexible substrate 21, a second transparent ITO electrode layer 22 arranged on a surface of the second transparent flexible substrate 21, and a second vertical alignment layer 23 coated on the second ITO electrode layer 22. An adjustment region 4 is formed between the upper substrate 1 and the lower substrate 2 through a packaging plastic frame 3, the first vertical alignment layer 13 and the second vertical alignment layer 23 faces the adjustment region 4, and supporting structures 5 are provided in the adjustment region 4.

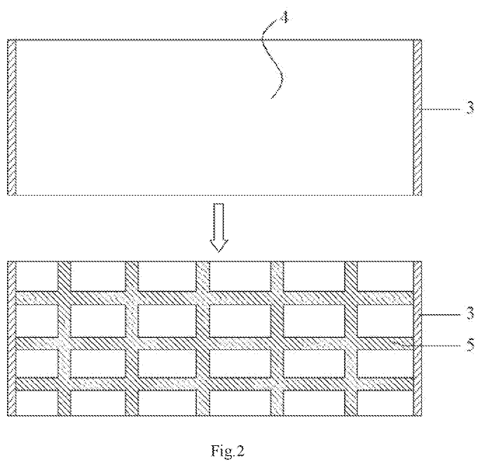

Combined FIG. 1 and FIG. 2 (overlooking view), this embodiment provides a method for manufacturing the above flexible liquid crystal optical shutter, comprising the following steps:

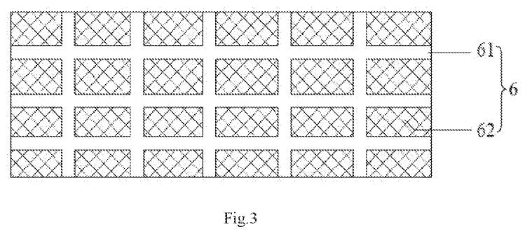

1) Preparation of a box body: taking an upper substrate 1 and a lower substrate 2, the upper substrate 1 comprises a first transparent flexible substrate 11, a first transparent ITO electrode layer 12 arranged on a surface of the first transparent flexible substrate 11, and a first vertical alignment layer 13 coated on the first ITO electrode layer 12, and the lower substrate 2 comprises a second transparent flexible substrate 21, a second transparent ITO electrode layer 22 arranged on a surface of the second transparent flexible substrate 21, and a second vertical alignment layer 23 coated on the second ITO electrode layer 22; the upper substrate 1 and the lower substrate 2 are arranged oppositely and a packaging plastic frame 3 is bonded, the packaging plastic frame 3 packaging the two transparent flexible conductive substrates to form an adjustment region 4, the first alignment layer 13 and the second alignment layer 23 faces the adjustment region 4, and photo spacers (unmarked in the figure) for controlling the distance between the upper substrate 1 and the lower substrate 2 is arranged in the adjustment region 4, thus to obtain the box body;
2) Preparation of a liquid crystal mixture: weighing 8 parts by mass of liquid crystal monomer HCM009, 1.5 parts by mass of photoinitiator IR651, 84.5 parts by mass of negative liquid crystal HNG30400-200, and 2 parts by mass of dichroic black dye under the condition of yellow light, and mixing them uniformly to obtain a liquid crystal mixture;
3) Filling and orientation of the liquid crystal mixture: heating the liquid crystal mixture to 60° C. under the condition of yellow light to convert the liquid crystal into an isotropic liquid state, then filling the box body with the liquid crystal mixture by capillary force at this temperature, and keeping the temperature at 60° C. on the heating stage for 30 min, in order that the liquid crystal mixture may be well oriented;
4) Ultraviolet light-induced polymerization: taking a mask 6 with a transparent portion 61 and an opaque portion 62 as shown in FIG. 3, placing the mask 6 above the box body for the optical mask of the liquid crystal mixture (the mask 6 is not shown in FIG. 2 due to the spatial positional relationship), and irradiating the liquid crystal mixture with ultraviolet light of 90 mW/cm² for 5 minutes, to polymerize the liquid crystal mixture corresponding to the position of transparent portion 61 to form supporting structures 5;
5) Then washing the residue of the dark portion of liquid crystal mixture which is not cured on the circumference of the box body with ethanol, removing the mask 6, and exposing the box body to ultraviolet light of 30 mW/cm² for 10 minutes to obtain a flexible liquid crystal optical shutter with supporting structures 5.

A mask with 300×300 μm² dark square pattern is used in this embodiment, and the mask has transparent boundary lattices (transparent portion) with widths of 30 μm. Before irradiation with ultraviolet light in the step (5), the liquid crystal mixture is free in the supporting structures. After irradiation with ultraviolet light, the photopolymerizable liquid crystal monomers in the liquid crystal mixture and the photoinitiator are polymerized under the action of the ultraviolet light to form a polymer network, and the negative liquid crystal and the dye molecules are dispersed in the polymer network. Since the light intensity used in step (5) is lower than the light intensity used for preparation of the supporting structures in step (4), the curing degree of photopolymerizable liquid crystal monomers that are not cured in step (4) is relatively low after the second irradiation with ultraviolet light. The formed polymer network is suitable for light adjustment after subsequent voltage application.

### Embodiment 2

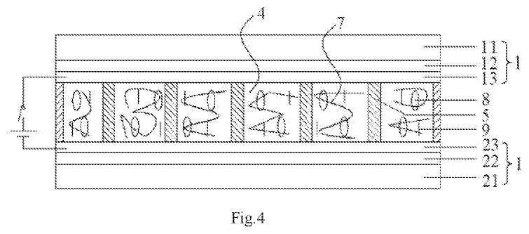

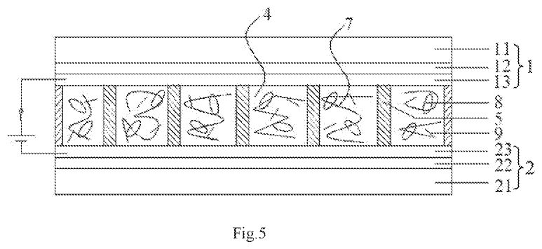

Referring to FIG. 4 and FIG. 5, taking the flexible liquid crystal optical shutter in Embodiment 1, the transparent ITO electrode layer 13 and the ITO electrode layer 23 of the flexible liquid crystal optical shutter is electrically connected with two poles of a power assembly, respectively, and the power assembly may comprise an arbitrary function generator and an oscilloscope. A voltage regulator is integrated in an AC power supply to make the voltage of the power supply controllable. By controlling the power on and power off of a switch and the voltage of the power supply, a voltage could be applied between the upper and lower substrates of the flexible liquid crystal optical shutter to form an electric field.

When no voltage is applied, the negative liquid crystal 8 and the dichroic black dye molecules 9 are arranged in a single domain with the flexible transparent substrates, and are uniformly dispersed in the polymer network 7 formed by the photopolymerizable liquid crystal monomers, so that when no voltage is applied, the box body is almost transparent, and the transmittance is highest at the moment. Since the supporting structures 5 produced by optical mask is distributed between the upper substrate 1 and the lower substrate 2, the bending-resistant stability of the flexible liquid crystal optical shutter is greatly enhanced.

When a voltage is applied between the upper substrate 1 and the lower substrate 2, the negative liquid crystal 8 turns toward a direction parallel to the substrates, and drives the dichroic black dye molecules 9 to rotate. During the process of the applying voltage, the negative liquid crystal after turning and dye molecules are arranged randomly in the box body due to the presence of the supporting structures 5 and irregularly distributed around the supporting structures, so that the light scattering phenomenon is enhanced, the liquid crystal optical shutter converts from a light transmission state to a light scattering state, and realizes the adjustment and control of the degree of fuzziness of the flexible optical shutter.

The performance of the present flexible transparent OLED displays is affected by poor visibility after power-on due to their inability to display as black, while some dye-doped liquid crystal (LC) and electrochromic devices may absorb incident light to produce black by using the absorbed optical shutters, such as suspended particles. However, the objects behind display panels cannot be completely hidden only by the light absorption. In the entire application of voltage, the phenomenon of dichroic black dye molecules absorbs light, made the flexible liquid crystal optical shutter higher haze, and achieved good masking effect.

### Embodiment 3

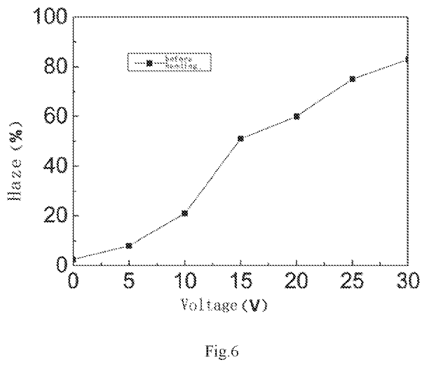

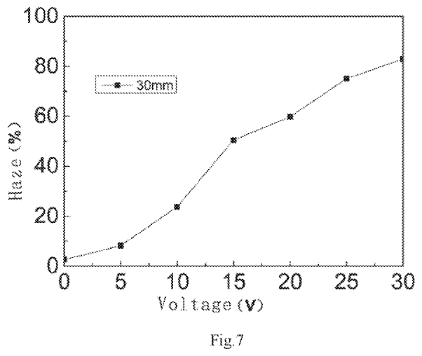

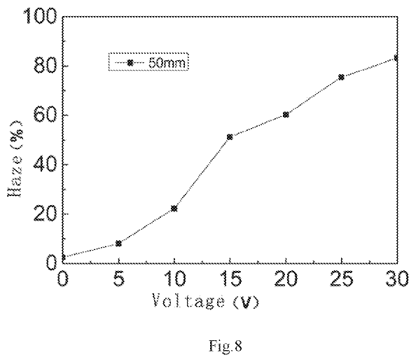

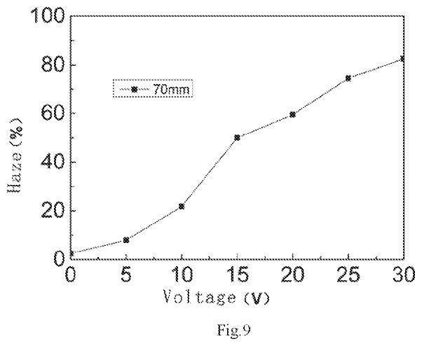

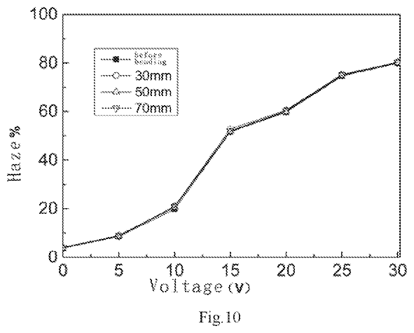

Taking the flexible liquid crystal optical shutter in Embodiment 1, placing it on cylinders of different diameters, and bent for a period of time to measure the bending photoelectric characteristics. The specific operation is as follows: the flexible liquid crystal shutter is respectively placed on cylinders of R=30 mm, 50 mm, and 70 mm, and removed from the cylinders after 24 hours, and then the haze is measured when no voltage applied and a voltage applied. The results are shown in FIGS. 6-10, wherein FIG. 6 is a haze curve diagram of the flexible liquid crystal optical shutter before bending, FIG. 7 is a haze curve diagram after bending by the cylinder of R=30 mm for 24 h, FIG. 8 is a haze curve diagram after bending by the cylinder of R=50 mm for 24 h, and FIG. 9 is a haze curve diagram after bending by the cylinder of R=70 mm for 24 h. For intuitively observing the effects of bending of the flexible liquid crystal optical shutter by different cylinders, an overlying diagram of the haze curves in FIGS. 6-9 is provided now as shown in FIG. 10. The experimental results show that, compared with the flexible liquid crystal optical shutter before bending, the flexible liquid crystal optical shutter provided by the present invention has almost no change in haze after bending by the cylinders of different diameters, indicating that the flexible liquid crystal optical shutter of the present invention has relatively good bending-resistant mechanical stability, which conforms to the characteristics of flexible optical shutters.

### Embodiment 4

This embodiment provides a flexible liquid crystal optical shutter, which is manufactured by the following steps:

1) Preparation of a box body: taking an upper substrate and a lower substrate, the upper substrate comprises a transparent flexible substrate I, a first transparent ITO electrode layer arranged on a surface of the transparent flexible substrate, and a first vertical alignment layer coated on the first ITO electrode layer, and the second lower substrate comprises a transparent flexible substrate, a second transparent ITO electrode layer arranged on a second surface of the transparent flexible substrate, and a second vertical alignment layer coated on the second ITO electrode layer; the upper substrate and the lower substrate are arranged oppositely and a packaging plastic frame is bonded, the packaging plastic frame packaging the two transparent flexible conductive substrates to form an adjustment region, the first alignment layer and the second alignment layer faces the adjustment region, and photo spacers (unmarked in the figure) for controlling the distance between the upper substrate and the lower substrate is arranged in the adjustment region, thus to obtain the box body;
2) Preparation of a liquid crystal mixture: weighing 12 parts by mass of liquid crystal monomer HCM009, 0.5 parts by mass of photoinitiator IR651, 91 parts by mass of negative liquid crystal HNG30400-200, and 0.5 parts by mass of dichroic black dye under the condition of yellow light, and mixing them uniformly to obtain a liquid crystal mixture;
3) Filling and orientation of the liquid crystal mixture: heating the liquid crystal mixture to 60° C. under the condition of yellow light to convert the liquid crystal into an isotropic liquid state, then filling the box body with the liquid crystal mixture by capillary force at this temperature, and keeping the box body temperature at 60° C. on the heating stage for 30 min, in order that the liquid crystal mixture may be well oriented;
4) Ultraviolet light-induced polymerization: taking a mask with a transparent portion and an opaque portion, placing the mask above the box body for the optical mask of the liquid crystal mixture, and irradiating the liquid crystal mixture with ultraviolet light of 100 mW/cm² for 5 minutes, to polymerize the liquid crystal mixture corresponding to the position of transparent portion to form supporting structures;
5) Then, washing the residue of the dark portion of liquid crystal mixture which is not cured on the circumference of the box body with ethanol, removing the mask, and exposing the box body to ultraviolet light of 25 mW/cm² for 10 minutes to obtain a flexible liquid crystal optical shutter with supporting structures.

### Embodiment 5

This embodiment provides a flexible liquid crystal optical shutter, which is manufactured by the following steps:

1) Preparation of a box body: taking an upper substrate and a lower substrate, the upper substrate comprises a first transparent flexible substrate, a first transparent ITO electrode layer arranged on a surface of the first transparent flexible substrate, and a first vertical alignment layer coated on the first ITO electrode layer, and the second lower substrate comprises a second transparent flexible substrate, a second transparent ITO electrode layer arranged on a surface of the second transparent flexible substrate, and a second vertical alignment layer coated on the second ITO electrode layer; the upper substrate and the lower substrate are arranged oppositely and a packaging plastic frame is bonded, the packaging plastic frame packaging the two transparent flexible conductive substrates to form an adjustment region, the first alignment layer and the second alignment layer faces the adjustment region, and photo spacers (unmarked in the figure) for controlling the distance between the upper substrate and the lower substrate is arranged in the adjustment region, thus to obtain the box body;
2) Preparation of a liquid crystal mixture: weighing 12 parts by mass of liquid crystal monomer HCM009, 0.5 parts by mass of photoinitiator IR651, 91 parts by mass of negative liquid crystal HNG30400-200, and 0.5 parts by mass of dichroic black dye under the condition of yellow light, and mixing them uniformly to obtain a liquid crystal mixture;
3) Filling and orientation of the liquid crystal mixture: heating the liquid crystal mixture to 60° C. under the condition of yellow light to convert the liquid crystal into an isotropic liquid state, then filling the box body with the liquid crystal mixture by capillary force at this temperature, and keeping the box body temperature at 60° C. on the heating stage for 30 min, in order that the liquid crystal mixture may be well oriented;
4) Ultraviolet light-induced polymerization: taking a mask with a transparent portion and an opaque portion, placing the mask above the box body for the optical mask of the liquid crystal mixture, and irradiating the liquid crystal mixture with ultraviolet light of 80 mW/cm² for 5 minutes, to polymerize the liquid crystal mixture corresponding to the position of transparent portion to form supporting structures;
5) Then, washing the residue of the dark portion of liquid crystal mixture which is not cured on the circumference of the box body with ethanol, removing the mask, and exposing the box body to ultraviolet light of 35 mW/cm² for 10 minutes to obtain a flexible liquid crystal optical shutter with supporting structures.

### Embodiment 6

This embodiment is the same as Embodiment 5 and the differences lies in that the liquid crystal mixture comprises 12 parts by mass of liquid crystal monomer HCM009, 0.5 parts by mass of photoinitiator IR651, and 91 parts by mass of negative liquid crystal HNG60700-200.

1. A method for manufacturing a flexible liquid crystal optical shutter, comprising the following steps:
S1, one of taking and manufacturing a box body comprising an upper substrate and a lower substrate, which are arranged oppositely, where the upper substrate comprises a first transparent flexible substrate, a first conductive layer and a first vertical alignment layer, which are sequentially stacked arranged; where the lower substrate comprises a second transparent flexible substrate, a second conductive layer and a second vertical alignment layer, which are sequentially stacked arranged; an adjustment region is formed between the upper substrate and the lower substrate, and the first vertical alignment layer and the second vertical alignment layer faces the adjustment region;
S2, filling the adjustment region with a liquid crystal mixture, where the liquid crystal mixture comprises:
a photopolymerizable liquid crystal monomer;
a photoinitiator; and
a negative liquid crystal;
S3, placing a mask with a transparent portion and an opaque portion above the box body, and irradiating the mask with ultraviolet light to polymerize the liquid crystal mixture corresponding to the position of transparent portion to form supporting structures; and
S4, removing the mask, and irradiating the box body with an intensity of the ultraviolet light of 25-35 mW/cm².

2. The method for manufacturing the flexible liquid crystal optical shutter of claim 1, wherein the intensity of the ultraviolet light in step S3 is 80-100 mW/cm².

3. The method for manufacturing the flexible liquid crystal optical shutter of claim 1, wherein the irradiation time of the ultraviolet light in step S3 is 4-6 min.

4. The method for manufacturing the flexible liquid crystal optical shutter of claim 1, wherein the irradiation time of the ultraviolet light in step S4 is 8-12 min.

5. The method for manufacturing the flexible liquid crystal optical shutter of claim 1, wherein the liquid crystal mixture comprises 8-12 parts by mass of polymerizable liquid crystal monomer, 0.5-1.5 parts by mass of photoinitiator, and 84.5-91 parts by mass of negative liquid crystal.

6. The method for manufacturing the flexible liquid crystal optical shutter of claim 1, wherein the liquid crystal mixture further comprises a dichroic dye.

7. The method for manufacturing the flexible liquid crystal optical shutter of claim 1, wherein the polymerizable liquid crystal monomer is HCM009.

8. The method for manufacturing the flexible liquid crystal optical shutter of claim 1, wherein the photoinitiator is IR651.

9. The method for manufacturing the flexible liquid crystal optical shutter of claim 1, wherein the first conductive layer or the second conductive layer is one of an ITO layer or a silver nanowire transparent electrode layer.

10. A flexible liquid crystal optical shutter manufactured by the method for manufacturing the flexible liquid crystal optical shutter of claim 1.
